(19) United States
(12) Patent Application Publication
(10) Pub. No.: US 2006/0214289 A1
(43) Pub. Date: Sep. 28, 2006

(54) Gallium nitride material-based monolithic microwave integrated circuits

(75) Inventor: Allen W. Hansen, Cary, NC (US)

Correspondence Address: WOLF GREENFIELD & SACKS, PC, FEDERAL RESERVE PLAZA, 600 ATLANTIC AVENUE, BOSTON, MA, 02210-2206, US

(73) Assignee: Nitronex Corporation, Raleigh, NC (US)

(21) Appl. No.: 11/261,942

(22) Filed: Oct. 28, 2005

Related U.S. Application Data
(60) Provisional application No. 60/622,871, filed on Oct. 28, 2004.

(51) Int. Cl. H01L 23/34

(52) U.S. Cl. 257/728

(57) ABSTRACT

Monolithic microwave integrated circuits are provided. The MMICs include at least one semiconductor material-based device (e.g., a gallium nitride material-based device) and may also include one or more additional circuit elements. The circuit elements may be active circuit elements (e.g., semiconductor material-based devices such as transistors or diodes) or passive circuit elements (e.g., inductors, capacitors, resistors). The MMICs can exhibit excellent electrical properties including high output powers, high power densities, wide bandwidths, high operating voltages, high efficiencies, high gains, as well as the ability to transmit signals at high frequencies (e.g., greater than 2 GHz) and operate at higher temperatures (e.g., greater than or equal to 150° C.), amongst others.

### RELATED APPLICATION

This application claims priority to U.S. Provisional Patent Application Ser. No. 60/622,871, filed Oct. 28, 2004, which is incorporated herein by reference.

### FIELD OF INVENTION

The invention relates generally to monolithic microwave integrated circuits (MMICs), and, more particularly, to gallium nitride material-based MMICs.

### BACKGROUND OF INVENTION

Monolithic microwave integrated circuits include at least one semiconductor device and, typically, other circuit elements (e.g., inductors, capacitors, resistors) that are arranged to perform a desired electrical function. The device(s) and circuit elements are formed on a substrate to create a monolithic structure. MMICs are used in a variety of applications including amplifiers (e.g., power and low noise), switches, and voltage control oscillators.

Gallium nitride semiconductor materials include gallium nitride (GaN) and its alloys such as aluminum gallium nitride (AlGaN), indium gallium nitride (InGaN), and aluminum indium gallium nitride (AlInGaN). These materials are semiconductor compounds that have a relatively wide bandgap which permits highly energetic electronic transitions to occur.

### SUMMARY OF INVENTION

Monolithic microwave integrated circuits and methods associated with the same are provided.

In one aspect, the invention provides a MMIC. The MMIC comprises a silicon substrate; and, at least one gallium nitride material-based device formed on the silicon substrate. The MMIC comprises at least one circuit element.

In another aspect, the invention provides a MMIC. The MMIC comprises a silicon substrate; and, at least one semiconductor material-based device formed on the silicon substrate. The MMIC is adapted to operate at a power density of at least 2 W/mm.

In one aspect, the invention provides a MMIC designed to transmit an output signal. The MMIC comprises a silicon substrate; and, at least one semiconductor material-based device formed on the silicon substrate. The MMIC is adapted to transmit an output signal at a frequency of greater than or equal to 3 GHz at an operating voltage greater than or equal to 28 V.

Other aspects, embodiments and features of the invention will become apparent from the following detailed description of the invention when considered in conjunction with the accompanying drawings. The accompanying figures are schematic and are not intended to be drawn to scale. In the figures, each identical, or substantially similar component that is illustrated in various figures is represented by a single numeral or notation. For purposes of clarity, not every component is labeled in every figure. Nor is every component of each embodiment of the invention shown where illustration is not necessary to allow those of ordinary skill in the art to understand the invention. All patent applications and patents incorporated herein by reference are incorporated by reference in their entirety. In case of conflict, the present specification, including definitions, will control.

### BRIEF DESCRIPTION OF DRAWINGS

FIG. 1 illustrates a MMIC according to one embodiment of the invention.

FIGS. 2A-2D are respective block diagrams of MMIC amplifiers according to one embodiment of the invention.

FIGS. 3A and 3B respectively illustrate a cross-section of and top view of a transistor building block structure suitable for use in a MMIC according to one embodiment of the invention.

FIG. 4 is a plan view of a transistor unit cell suitable for use in a MMIC according to one embodiment of the invention.

FIG. 5 is a plan view of a power transistor suitable for use in a MMIC according to one embodiment of the invention.

FIG. 6 shows a two-stage MMIC amplifier according to one embodiment of the invention.

FIG. 7 shows simulated data obtained with the two-stage MMIC amplifier described in Example 1.

### DETAILED DESCRIPTION

The invention provides monolithic microwave integrated circuits. The MMICs include at least one semiconductor material-based device (e.g., a gallium nitride material-based device) and may also include one or more additional circuit elements. The circuit elements may be active circuit elements (e.g., semiconductor material-based devices such as transistors or diodes) or passive circuit elements (e.g., inductors, capacitors, resistors). The phrase “monolithic” means that the semiconductor material-based device and the additional circuit element(s) of the MMIC are formed on, and/or in the bulk of, the substrate. The device(s) and other circuit element(s) are arranged to perform a desired electrical function (e.g., signal amplification). The substrate may be silicon. The device(s) may be formed on, or in, a gallium nitride material region formed on the substrate. As described further below, MMICs of the invention can exhibit excellent electrical properties including high output powers, high power densities, wide bandwidths, high operating voltages, high efficiencies, high gains, as well as the ability to transmit signals at high frequencies (e.g., greater than 2 GHz) and operate at higher temperatures (e.g., greater than or equal to 150° C.), amongst others.

When a structure (e.g., layer and/or device) is referred to as being “on” or “over” another structure (e.g., layer or substrate), it can be directly on the structure, or an intervening structure (e.g., a layer, air gap) also may be present. A structure that is “directly on” another structure means that no intervening structure is present. It should also be understood that when a structure is referred to as being “on” or “over” another structure, it may cover the entire structure, or a portion of the structure.

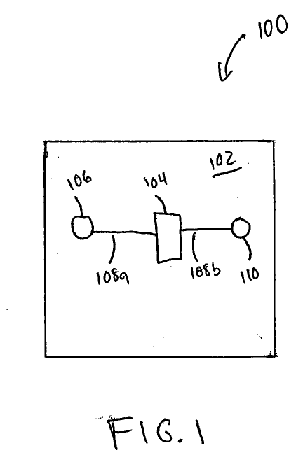

FIG. 1 schematically illustrates a MMIC 100 according to one embodiment of the invention. MMIC 100 includes a number of different circuit elements formed on a substrate 102. In the illustrative embodiment, a semiconductor device 104 is connected to an input pad 106 via transmission lines 108a and to an output pad 110 via transmission lines 108b.

It should be understood that the MMIC shown in FIG. 1 is only a schematic representation. Any suitable MMIC structure may be used Typically, MMIC structures will include additional circuit elements, and other features. In some embodiments, MMIC includes a plurality of semiconductor devices. For example, certain suitable MMIC structures (e.g., passive circuit elements such as planar inductors, metal-insulator-metal capacitors, thin film resistors) have been described in “Design Considerations for Monolithic Microwave Circuits,” IEEE Transactions on Microwave Theory and Techniques, Vol. MTT-29, No. 6, June 1981, which is incorporated herein by reference.

It should also be understood that MMICs of the invention may be electrically connected to other circuit elements that are not monolithically integrated on the same substrate. That is, the other circuit elements may be external to the substrate.

In this embodiment, the MMIC receives an input signal at pad 106 which is transmitted to device 104. The device processes the signal, as desired, which is transmitted to the output pad and, then, from the MMIC as an output signal. For example, when MMIC 100 is a power amplifier, the device may amplify the input signal to form the output signal.

Transmission lines 108a may form part of an input matching network and transmission lines 108b may form part of an output matching network. A number of variables associated with the transmission lines (e.g., number, composition, dimensions) may be selected to achieve the desired impedance matching.

The input matching network may be designed to transform the input impedance of the device to a desired impedance (e.g., to a larger impedance to ease any subsequent external matching). The output matching network may be designed to transform the output impedance of the device to a desired impedance (e.g., to a larger impedance to ease any subsequent external matching).

It should be understood that typically the input and output matching networks include additional components. For example, the matching networks can comprise any component or feature capable of transforming impedance. Such components include devices (e.g., capacitors, inductors) that transform impedance by a known amount. Thus, the devices may be connected to form a network that transforms the impedance as desired. Those of ordinary skill in the art understand how to design suitable matching networks.

In some embodiments, device 104 is a transistor. Suitable transistor structures have been described in commonly-owned U.S. Patent Application Publication No. 2005-016775 which is incorporated herein by reference and is based on U.S. patent application Ser. No. 10/913,297, entitled “Gallium Nitride Material Transistors and Methods Associated with the Same”, filed Aug. 5, 2004. Transistor structures are described further below. As noted above, the MMIC may include more than one transistor formed on the substrate.

In some embodiments, device 106 is a diode. As noted above, the MMIC may include more than one diode formed on the substrate.

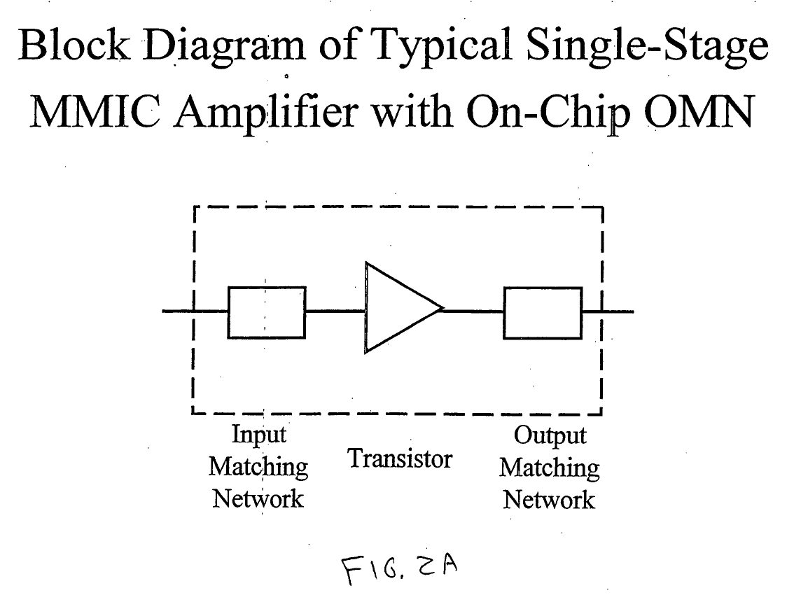

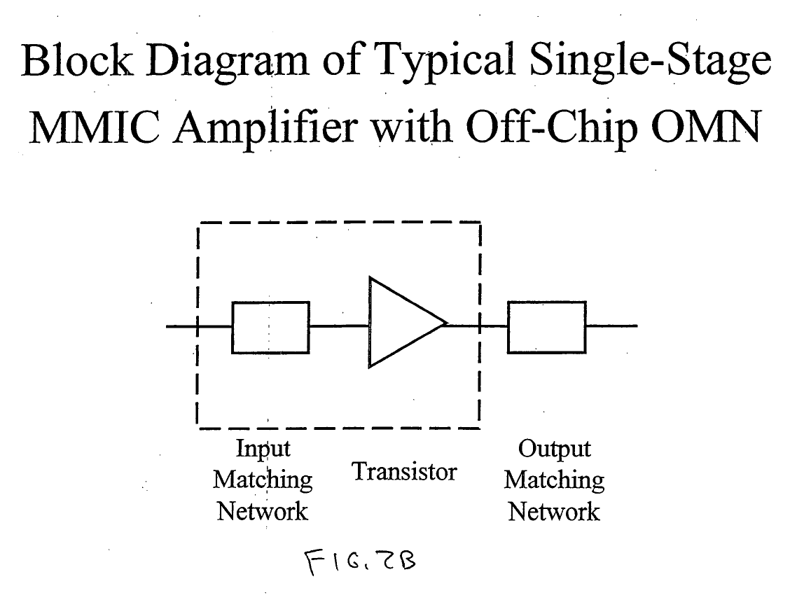

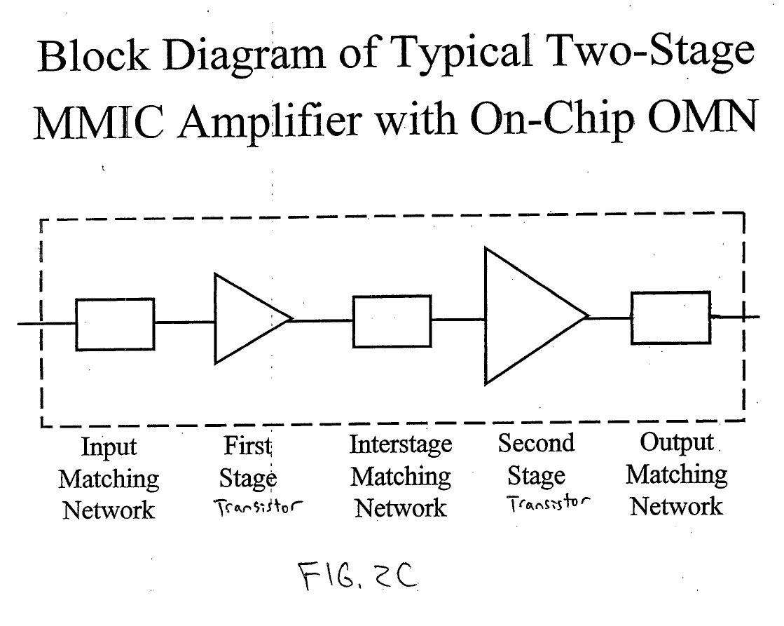

FIG. 2A is a block diagram of a single-stage MMIC amplifier according to one embodiment of the invention. The amplifier includes an input matching network, a transistor and an output matching network—all formed monolithically on the same substrate (i.e., “on-chip”). It should be understood that the matching networks and transistor are all electrically connected, for example, using transmission lines.

FIG. 2B is a block diagram of a single-stage MMIC amplifier according to one embodiment of the invention. The amplifier includes an input matching network, a transistor and an output matching network. In this embodiment, the input matching network and the transistor are formed on the same substrate, while the output matching network is external to the substrate (i.e., “off-chip”). It should be understood that the matching networks and transistor are all electrically connected, for example, using transmission lines.

FIG. 2C is a block diagram of a two-stage MMIC amplifier according to one embodiment of the invention. The amplifier includes an input matching network, a first stage transistor, an interstage matching network, a second stage transistor and an output matching network—all formed on the same substrate (i.e., “on-chip”). It should be understood that the matching networks and transistors are all electrically connected, for example, using transmission lines.

FIGS. 2D is a block diagram of a two-stage MMIC amplifier according to one embodiment of the invention. The amplifier includes an input matching network, a first stage transistor, an interstage matching network, a second stage transistor formed on the same substrate, while an output matching network is external to the substrate (i.e., “off-chip”). It should be understood that the matching networks and transistors are all electrically connected, for example, using transmission lines.

FIG. 6 is an example of a two-stage MMIC amplifier 190 according to one embodiment of the invention. In this embodiment, the MMIC includes a first transistor 204 (e.g., having a total gate periphery of 0.6 mm) and a second transistor 224 (e.g., having a total gate periphery of 6 mm). An electrical signal is introduced to the circuit by way of bond wire connected to bond pad 200. The impedance at bond pad 200 may be increased by an input matching network. In this embodiment, the input matching network comprises an inductor 202. The first stage of signal gain is provided by transistor 204. Resistor 208 and capacitor 206 provide parallel feedback to promote stability of transistor 204 and to flatten the gain of the overall amplifier. The drain current used to bias transistor 204 is brought in by way of inductor 210 that in conjunction with shunt capacitor 212 isolate the 28 V dc supply from the RF path of the circuit. The amplifier includes an inter-stage matching network comprised of inductor elements 214, 218 and 220, as well as shunt capacitor elements 216 and 222. The interstage topology and element values were designed to improve RF energy transfer between transistors 204 and 224. Inductor 220 and shunt capacitor 222 also serve to provide gate bias to output stage transistor 224. The final stage of signal gain is provided by transistor 224. The amplified signal—is taken off chip by way of bond wire connected to bond pad 226. In this embodiment, output matching is performed off chip in order to achieve a desirable level of drain efficiency.

It should be understood that MMICs of the invention can include additional monolithically integrated circuit networks such as bias networks, power control circuitry, ESD protection circuitry, feedback circuitry, and stabilization elements (e.g., for thermal and electrical stability).

It should also be understood that MMICs of the invention may have other circuit designs than those shown herein. The specific design depends, in part, on the particular application of the MMIC. MMICs of the invention may be used in a wide variety of applications. For example, MMICs may be used as power amplifiers, low noise amplifiers, switches, oscillators (e.g., voltage-controlled oscillators), mixers and doublers.

As noted above, MMICs of the invention may exhibit excellent electrical properties including high power densities, high output power, high operating voltages, high efficiencies, low noise figure characteristics, as well as the ability to transmit signals at high frequencies (e.g., greater than 2 GHz), amongst others.

MMICs of the invention may have high output powers and/or high power densities. Power density (W/mm) is the output power divided by total gate width of the output stage of the MMIC, as known to those of skill in the art. Output power may be measured using standard techniques and power density may be calculated from the measurement.

For example, transistors of the invention may have power densities of greater than or equal to 2.0 W/mm (e.g., between about 2.0 W/mm and about 15.0 W/mm); or, greater than or equal to 4.0 W/mm; or, greater than or equal to 8.0 W/mm.

In some embodiments, the output power may be greater than or equal to 10 W (e.g., between about 10 W and about 1000 W); or, greater than or equal to 100 W; or, greater than or equal 500 W.

Efficiency (i.e., drain efficiency) is defined as the output power divided by the product of the drain current and the drain voltage. MMICs of the invention may operate at efficiencies of greater than or equal to 20% (e.g., between 20% and 30%). In some embodiments, the transistors operate at efficiencies of greater than or equal to 30%; and, in some embodiments, the transistors operate at efficiencies of greater than or equal to 40%.

MMICs of the invention can transmit output signals at high frequencies. For example, MMICs may be used to transmit output signals at frequencies of greater than or equal to 0.1 GHz. In some embodiments, the MMICs may be used to transmit output signals at frequencies of greater than or equal to 3 GHz; or, greater than or equal to 6 GHz; or, greater than or equal to 18 GHz. In some cases, the MMICs may be used to transmit output signals at frequencies of up to 77 GHz.

The MMICs are particularly useful in transmitting output signals within certain high frequency bands. For example, the MMICs are useful for transmitting output signals within the X-Band (e.g., between 8 GHz and 12 GHz and 8 GHz-10.5 GHz); or, within C-Band (e.g., between 4 GHz and 8 GHz). Notably, signals may be transmitted at the above-described frequencies including the above-described frequency bands at the high output power and power density numbers noted above, as well as at the high efficiencies noted above (and gains noted below).

In some cases, MMICs are operated at operating voltages (i.e., drain voltages) of greater than or equal to 28 Volts; or, greater than or equal to 48 Volts. In some cases, the operating voltage may be up to 120 Volts or up to 50 Volts (e.g., 28 Volts or 48 Volts). Suitable gate voltages may be between 0 Volts and −10 Volts. The above-described properties are achievable at these operating voltages and the above-described transmission frequencies.

MMICs of the invention may also produce power gain. Power gain (or gain) is defined as the output power divided by the input power and may be expressed in units of dB. Transistors of the invention may have a gain of greater than or equal to 5 dB. In some embodiments, the gain may be greater than or equal to 12 dB (e.g., between 12 and 15).

It should be understood that MMICs of the invention may have other combinations of properties.

FIGS. 3A and 3B respectively illustrate a cross-section of and top view of a transistor building block structure 10 according to one embodiment of the invention. As described further below, a plurality of the building block structures 10 may be combined to construct a power transistor device. The power transistor device may be a component of MMICs of the invention (e.g., device 104), as described above.

In the illustrative embodiment, structure 10 includes a gallium nitride material region 12. In the illustrative embodiment, the transistor structure includes a source electrode 14, a drain electrode 16 and a gate electrode 18 formed on the gallium nitride material region. The gallium nitride material region is formed on a substrate 20 and, as shown, a transition layer 22 may be formed between the substrate and the gallium nitride material region. The transistor includes a passivating layer 24 that protects and passivates the surface of the gallium nitride material region. In the illustrative embodiment, a via 26 is formed within the passivating layer in which the gate electrode is, in part, formed.

It should be understood that the transistor structure shown in FIGS. 3A and 3B is illustrative of an embodiment of the invention but should not be considered limiting. Other transistor structures are also within the scope of the present invention including transistor structures with different layer(s), different layer arrangements and different features.

FIG. 4 is a plan view of a transistor unit cell 30 according to one embodiment of the invention. In this embodiment, the transistor unit cell includes ten transistor building block structures. As shown, the source electrodes in the unit cell are connected to a common source pad 32; the gate electrodes are connected to a common gate pad 34; and, the drain electrodes are connected to a common drain pad 36. In the illustrative unit cell, ten gate electrodes are connected to the gate pad, six source electrodes are connected to source pad, and five drain electrodes are connected to the gate pad.

It should be understood that, in other embodiments of the invention, the transistor unit cell may include a different number of building block structures and/or have different types of electrode and pad connections.

FIG. 5 is a plan view of a power transistor 40 according to one embodiment of the invention. The power transistor includes multiple transistor unit cells 30 arranged in parallel. In the illustrative embodiment, the transistor includes eighteen unit cells, though other numbers of unit cells are possible. Respective drain pads 36 from the unit cells are aligned to form a drain bus 42. Respective source pads 32 are connected to a source bus 43 (FIG. 4); and, respective gate pads 34 are connected to a gate bus 44 (FIG. 4).

Transistors of the invention may operate in common source configuration. In this configuration, the source pads (and source electrodes) are connected to ground (e.g., via a through wafer-via to a ground plane on the backside of the structure), the input signal from a signal source is received by the gate pads (and gate electrodes), and the output signal is transmitted from the drain pads (and drain electrodes) to a load driven by the transistor. However, it is possible, for the transistors to operate in other configurations.

Referring again to FIG. 3A, gallium nitride material region 12 of the transistor structure functions as the active region. That is, the conductive channel extending from the source electrode to the drain electrode is formed in the gallium nitride material region. The gallium nitride material region comprises at least one gallium nitride material layer. As used herein, the phrase “gallium nitride material” refers to gallium nitride (GaN) and any of its alloys, such as aluminum gallium nitride (AlₓGa₍₁₋ₓ₎N), indium gallium nitride (In_{y}Ga_{(1-y)}N), aluminum indium gallium nitride (AlₓIn_{y}Ga_{(1-x-y)}N), gallium arsenide phosporide nitride (GaAsₐP_{b}N_{(1-a-b)}), aluminum indium gallium arsenide phosporide nitride (AlₓIn_{y}Ga_{(1-x-y)}AsₐP_{b}N_{(1-a-b)}), amongst others. Typically, when present, arsenic and/or phosphorous are at low concentrations (i.e., less than 5 weight percent). In certain preferred embodiments, the gallium nitride material has a high concentration of gallium and includes little or no amounts of aluminum and/or indium. In high gallium concentration embodiments, the sum of (x+y) may be less than 0.4, less than 0.2, less than 0.1, or even less. In some cases, it is preferable for the gallium nitride material layer to have a composition of GaN (i.e., x+y=0). Gallium nitride materials may be doped n-type or p-type, or may be intrinsic. Suitable gallium nitride materials have been described in commonly-owned U.S. Pat. No. 6,649,287 incorporated herein by reference.

In some cases, the gallium nitride material region includes only one gallium nitride material layer. In other cases, the gallium nitride material region includes more than one gallium nitride material layer. For example, the gallium nitride material region may include multiple layers (12a, 12b, 12c), as shown. In certain embodiments, it may be preferable for the gallium nitride material of layer 12b to have an aluminum concentration that is greater than the aluminum concentration of the gallium nitride material of layer 12a. For example, the value of x in the gallium nitride material of layer 12b (with reference to any of the gallium nitride materials described above) may have a value that is between 0.05 and 1.0 greater than the value of x in the gallium nitride material of layer 12a, or between 0.05 and 0.5 greater than the value of x in the gallium nitride material of layer 12a. For example, layer 12b may be formed of Al_{0.20}Ga_{0.80}N, while layer 12a is formed of GaN. This difference in aluminum concentration may lead to formation of a highly conductive region at the interface of the layers 12a, 12b (i.e., a 2-D electron gas region). In the illustrative embodiment, layer 12c may be formed of GaN.

Gallium nitride material region 12 also may include one or more layers that do not have a gallium nitride material composition such as other III-V compounds or alloys, oxide layers, and metallic layers.

The gallium nitride material region is of high enough quality so as to permit the formation of devices therein. Preferably, the gallium nitride material region has a low crack level and a low defect level. As described further below, transition layer 22 (particularly when compositionally-graded) may reduce crack and/or defect formation. Gallium nitride materials having low crack levels have been described in U.S. Pat. No. 6,649,287 incorporated by reference above. In some cases, the gallium nitride material region a crack level of less than 0.005 μm/μm². In some cases, the gallium nitride material region has a very low crack level of less than 0.001 μm/μm². In certain cases, it may be preferable for gallium nitride material region to be substantially crack-free as defined by a crack level of less than 0.0001 μm/μm².

In some embodiments, gallium nitride materials having low dislocation densities may be preferred. Suitable gallium nitride materials and processes for forming the same are described in commonly-owned, co-pending U.S. patent application Ser. No. 10/886,506, filed Jul. 7, 2004, entitled “III-Nitride Materials Including Low Dislocation Densities and Methods Associated With the Same” which is incorporated herein by reference.

In certain cases, the gallium nitride material region includes a layer or layers which have a monocrystalline structure. In some cases, the gallium nitride material region includes one or more layers having a Wurtzite (hexagonal) structure.

The thickness of the gallium nitride material region and the number of different layers are dictated, at least in part, by the requirements of the specific device. At a minimum, the thickness of the gallium nitride material region is sufficient to permit formation of the desired structure or device. The gallium nitride material region generally has a thickness of greater than 0.1 micron, though not always. In other cases, gallium nitride material region 12 has a thickness of greater than 0.5 micron, greater than 0.75 micron, greater than 1.0 microns, greater than 2.0 microns, or even greater than 5.0 microns.

As noted above, the device includes passivating layer 24 formed on the surface of gallium nitride material region 12. Suitable passivating layers (some of which also function as electrode-defining layers) have been described in commonly-owned U.S. Patent Application Publication No. 2005-0133818 which is incorporated herein by reference and is based on U.S. patent application Ser. No. 10/740,376, filed Dec. 17, 2003, entitled “Gallium Nitride Material Devices Including an Electrode-Defining Layer and Methods of Forming The Same”.

Suitable compositions for passivating layer 24 include, but are not limited to, nitride-based compounds (e.g., silicon nitride compounds), oxide-based compounds (e.g., silicon oxide compounds), polyimides, other dielectric materials, or combinations of these compositions (e.g., silicon oxide and silicon nitride). In some cases, it may be preferable for the passivating layer to be a silicon nitride compound (e.g., Si₃N₄) or non-stoichiometric silicon nitride compounds.

In certain preferred embodiments, substrate 20 is a silicon substrate. Silicon substrates may be preferred because they are readily available, relatively inexpensive and are of high crystalline quality.

As used herein, a silicon substrate refers to any substrate that includes a silicon surface. Examples of suitable silicon substrates include substrates that are composed entirely of silicon (e.g., bulk silicon wafers), silicon-on-insulator (SOI) substrates, silicon-on-sapphire substrate (SOS), and SIMOX substrates, amongst others. Suitable silicon substrates also include substrates that have a silicon wafer bonded to a second material or a silicon layer deposited on a second material. In these cases, the second material may be diamond, AIN, SiC or other polycrystalline materials. Silicon substrates having different crystallographic orientations may be used. In some cases, silicon (111) substrates are preferred. In other cases, silicon (100) substrates are preferred.

It should be understood that other types of substrates may also be used including sapphire, silicon carbide, indium phosphide, silicon germanium, gallium arsenide, gallium nitride material, aluminum nitride, or other Ill-V compound substrates. However, in embodiments that do not use silicon substrates, all of the advantages associated with silicon substrates may not be achieved.

Substrate 20 may have any suitable dimensions and its particular dimensions are dictated, in part, by the application and the substrate type. In some embodiments, it may be preferable to use substrates having relatively large diameters for gallium nitride material processing (e.g., greater than or equal to 100 mm and/or greater than or equal to about 150 mm) such as about 100 mm (or about 4 inches), about 150 mm (or about 6 inches), or about 200 mm (or about 8 inches), or even about 400 (or about 12 inches). Large diameters have the advantage of increasing the total device area for a given substrate. It should be understood that a gallium nitride material region grown on a substrate can have the same diameter as that of the substrate.

In some cases, it may be preferable for the substrate to be relatively thick, such as greater than about 125 micron (e.g., between about 125 micron and about 800 micron, or between about 400 micron and 800 micron). Relatively thick substrates may be easy to obtain, process, and can resist bending which can occur, in some cases, when using thinner substrates. In other embodiments, thinner substrates (e.g., less than 125 microns) are used. Though thinner substrates may not have the advantages associated with thicker substrates, thinner substrates can have other advantages including facilitating processing and/or reducing the number of processing steps. In some processes, the substrate initially is relatively thick (e.g., between about 200 microns and 800 microns) and then is thinned during a later processing step (e.g., to less than 150 microns).

Transition layer 22 may be formed on substrate 20 prior to the deposition of gallium nitride material region 12. The transition layer may accomplish one or more of the following: reducing crack formation in the gallium nitride material region 12 by lowering thermal stresses arising from differences between the thermal expansion rates of gallium nitride materials and the substrate; reducing defect formation in gallium nitride material region by lowering lattice stresses arising from differences between the lattice constants of gallium nitride materials and the substrate; and, increasing conduction between the substrate and gallium nitride material region by reducing differences between the band gaps of substrate and gallium nitride materials. The presence of the transition layer may be particularly preferred when utilizing silicon substrates because of the large differences in thermal expansion rates and lattice constant between gallium nitride materials and silicon. It should be understood that the transition layer also may be formed between the substrate and gallium nitride material region for a variety of other reasons. In some cases, for example when a silicon substrate is not used, the device may not include a transition layer.

The composition of transition layer 22 depends, at least in part, on the type of substrate and the composition of gallium nitride material region 12. In some embodiments which utilize a silicon substrate, the transition layer may preferably comprise a compositionally-graded transition layer having a composition that is varied across at least a portion of the layer. Suitable compositionally-graded transition layers, for example, have been described in commonly-owned U.S. Pat. No. 6,649,287, entitled “Gallium Nitride Materials and Methods,” filed on Dec. 14, 2000, which is incorporated herein by reference. Compositionally-graded transition layers are particularly effective in reducing crack formation in the gallium nitride material region by lowering thermal stresses that result from differences in thermal expansion rates between the gallium nitride material and the substrate (e.g., silicon). In some embodiments, when the compositionally-graded, transition layer is formed of an alloy of gallium nitride such as AlₓIn_{y}Ga_{(1-x-y)}N, AlₓGa₍₁₋ₓ₎N, or In_{y}Ga_{(1-y)}N, wherein 0≦x≦1,0≦y≦1. In these embodiments, the concentration of at least one of the elements (e.g., Ga, Al, In) of the alloy is typically varied across at least a portion of the cross-sectional thickness of the layer. For example; when the transition layer has an AlₓIn_{y}Ga_{(1-x-y)}N composition, x and/or y may be varied; when the transition layer has a AlₓGa₍₁₋ₓ₎N composition, x may be varied; and, when the transition layer has a In_{y}Ga_{(1-y)}N composition, y may be varied.

In certain preferred embodiments, it is desirable for the transition layer to have a low gallium concentration at a back surface which is graded to a high gallium concentration at a front surface. It has been found that such transition layers are particularly effective in relieving internal stresses within the gallium nitride material region. For example, the transition layer may have a composition of AlₓGa₍₁₋ₓ₎N, where x is decreased from the back surface to the front surface of the transition layer (e.g., x is decreased from a value of 1 at the back surface of the transition layer to a value of 0 at the front surface of the transition layer). The composition of the transition layer, for example, may be graded discontinuously (e.g., step-wise) or continuously. One discontinuous grade may include steps of AlN, Al_{0.6}Ga_{0.4}N and Al_{0.3}Ga_{0.7}N proceeding in a direction toward the gallium nitride material region.

In some cases, the transition layer has a monocrystalline structure.

It should be understood that, in some embodiments, transition layer 22 has a constant (i.e., non-varying) composition across its thickness.

The source, drain and gate electrodes may be formed of any suitable conductive material such as metals (e.g., Au, Ni, Pt), metal compounds (e.g., WSi, WSiN), alloys, semiconductors, polysilicon, nitrides, or combinations of these materials. In particular, the dimensions of the gate electrode can be important to device performance. In the illustrative embodiment, via 26 formed in the passivating layer defines (at least in part) the gate electrode dimensions. Thus, by controlling the shape of the via, it is possible to define desired gate dimensions. Suitable via and gate dimensions have been described in U.S. patent application Ser. No. 10/740,376, incorporated by reference above.

In some embodiments, electrodes may extend into the gallium nitride material region. For example, electrode material (e.g., metal) deposited on the surface of the gallium nitride material region may diffuse into the gallium nitride material region during a subsequent annealing step (e.g., RTA) when forming the electrode. In particular, the source and drain electrodes may include such a portion diffused into the gallium nitride material region. As used herein, such electrodes are still considered to be formed on the gallium nitride material region.

Source, gate and drain pads may be formed of any suitable conductive material such as metals (e.g., Au, Ni, Pt), metal compounds (e.g., WSi, WSiN), alloys, semiconductors, polysilicon, nitrides, or combinations of these materials. In some embodiments, the pads are formed of the same material as the corresponding electrodes.

The device shown in FIGS. 1A and 1B also includes an encapsulation layer 36 which, as known to those of skill in the art, encapsulates underlying layers of the structure to provide chemical and/or electrical protection. The encapsulation layer may be formed of any suitable material including oxides or nitrides.

It should be understood that the transistor structure may include other layers. For example, the transistor structure may include additional features not shown in FIGS. 1A and 1B. For example, the transistor structure may include a strain-absorbing layer formed directly on the surface of substrate 20. Suitable strain-absorbing layers have been described in commonly-owned, co-pending U.S. patent application Ser. No. 10/879,703, entitled “Gallium Nitride Materials and Methods Associated With the Same”, filed Jun. 28, 2004, which is incorporated herein by reference. In one embodiment, it may be preferable for the strain-absorbing layer to be very thin (e.g., thickness of between about 10 Angstroms and about 100 Angstroms) and formed of an amorphous silicon nitride-based material.

In some embodiments, other layers (e.g., intermediate layers) may be present. Suitable intermediate layers, for example, have been described and illustrated in U.S. Pat. No. 6,649,287, which was incorporated by reference above. In other embodiments of the invention, layer(s) shown herein may not be present. Other variations to the structures and devices shown herein would be known to those of skill in the art and are encompassed by the present invention.

Structures and devices of the present invention may be formed using methods that employ conventional processing techniques. In general the stack of material layers is formed on a substrate which is later processed (e.g., diced) to form the desired final structure (e.g., transistor).

For example, the layers and regions of the transistor structure of FIGS. 1A and 1B may be formed, patterned, etched and implanted using conventional techniques.

Transition layer 22 and gallium nitride material region 12 may be deposited, for example, using metal organic chemical vapor deposition (MOCVD), molecular beam epitaxy (MBE), and hydride vapor phase epitaxy (HVPE), amongst other techniques. The preferred technique may depend, in part, on the composition of the layers. An MOCVD process may be preferred. A suitable MOCVD process to form a transition layer (e.g., a compositionally-graded transition layer) and gallium nitride material region over a silicon substrate has been described in U.S. Pat. No. 6,649,287 incorporated by reference above. When the semiconductor material region has different layers, in some cases it is preferable to use a single deposition step (e.g., an MOCVD step) to form the entire gallium nitride material region. When using the single deposition step, the processing parameters are suitably changed at the appropriate time to form the different layers. In certain preferred cases, a single growth step may be used to form the transition layer and the gallium nitride material region.

When present, the stress-absorbing layer may be formed using techniques described in U.S. patent application Ser. No., 10/879,703 which is incorporated by reference above.

Passivating layer 24 may be deposited using any suitable technique. The technique used, in part, depends on the composition of the passivating layer. Suitable techniques include, but are not limited to CVD, PECVD, LP-CVD, ECR-CVD, ICP-CVD, evaporation and sputtering. When the passivating layer is formed of a silicon nitride material, it may be preferable to use PECVD to deposit the layer.

When present, via 26 may be formed within the passivating layer using an etching technique. A plasma etching technique is preferably used to form the via with controlled dimensions

Source, drain and gate electrodes may be deposited on the gallium nitride material region using known techniques such as an evaporation technique. In cases when the electrodes include two metals, then the metals are typically deposited in successive steps. The deposited metal layer may be patterned using conventional methods to form the electrodes. In some embodiments, an annealing step (e.g., RTA) may also be used in which the deposited electrode material diffuses into the gallium nitride material region, particularly when forming source and drain electrodes.

Suitable techniques for forming the passivating layer, via and electrodes have been described in commonly owned, co-pending U.S. patent application Ser. No. 10/740,376, which is incorporated herein by reference above.

Source, drain and gate electrode pads may also be deposited and patterned using known techniques.

In some embodiments, an isolation region may be formed which electrical isolates the active region. Suitable processes for forming isolation region have been described in commonly owned, co-pending U.S. patent application Ser. No. 10/879,795, filed Jun. 28, 2004, entitled “Gallium Nitride Material Structures Including Isolation Regions and Methods”, which is incorporated herein by reference above.

The above-described processes are used to form a semiconductor structure including the desired material layers and features. The structure may be further processed using conventional techniques to produced the desired structure. In some methods, the structure may be thinned from its backside. A metallic layer (e.g., gold) may then be deposited on the backside.

In some methods, the structure may be processed to include vias that extend from a backside of the structure. In some cases, the backside via may extend through the entire structure to form a through via. An electrode may be deposited in the backside via. Suitable backside vias and processes of forming the same, for example, have been described in commonly-owned U.S Pat. No. 6,611,002 and commonly-owned U.S. Patent Application Publication No. 2004-0130002 which is incorporated herein by reference and is based on U.S. patent application Ser. No. 10/650,122, entitled “Gallium Nitride Material Devices and Methods of Forming the Same”, filed Aug. 25, 2003, which is incorporated herein by reference.

Is It should be understood that the invention encompasses other methods than those specifically described herein. Also, variations to the methods described above would be known to those of ordinary skill in the art and are within the scope of the invention.

The following example is not limiting and is presented for purposes of illustration:

### EXAMPLE 1

This example describes characterization of GaN power MMIC formed on a Si substrate.

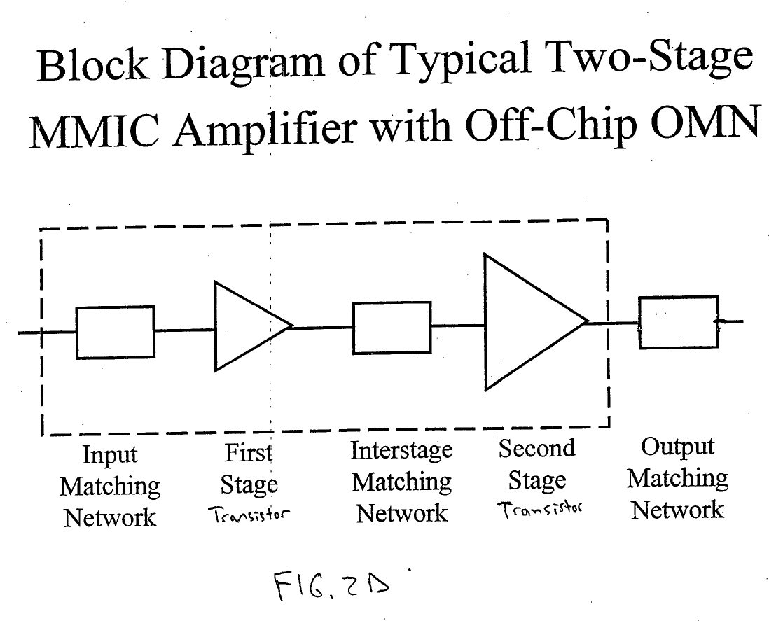

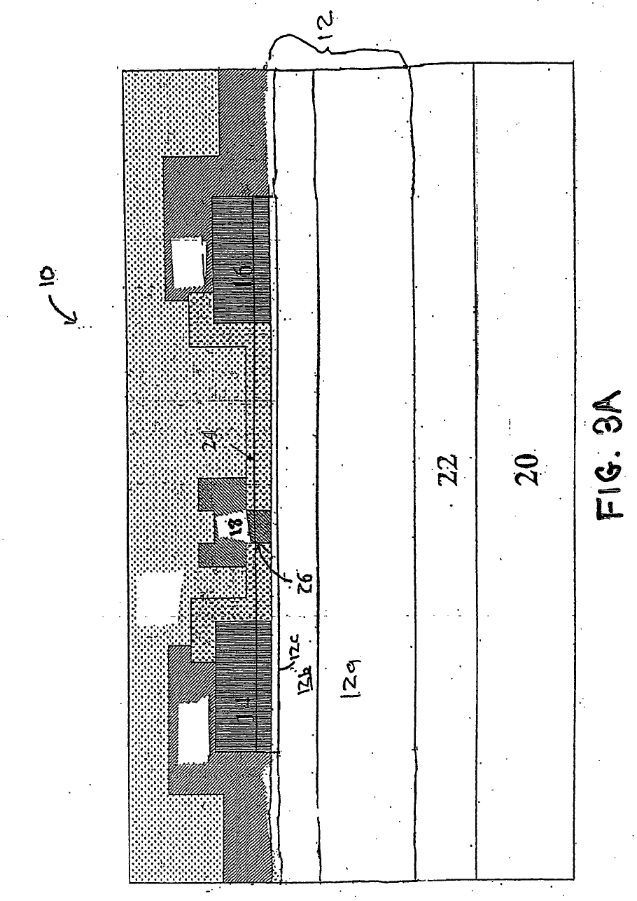

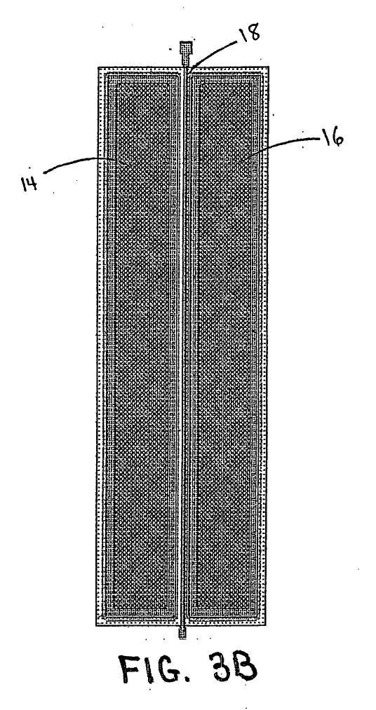

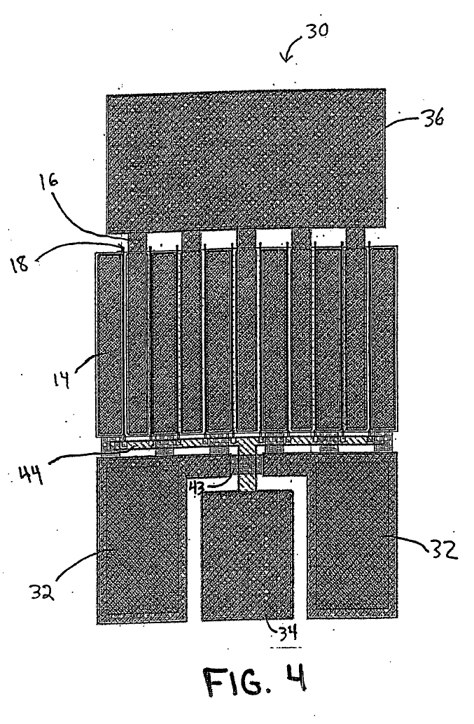

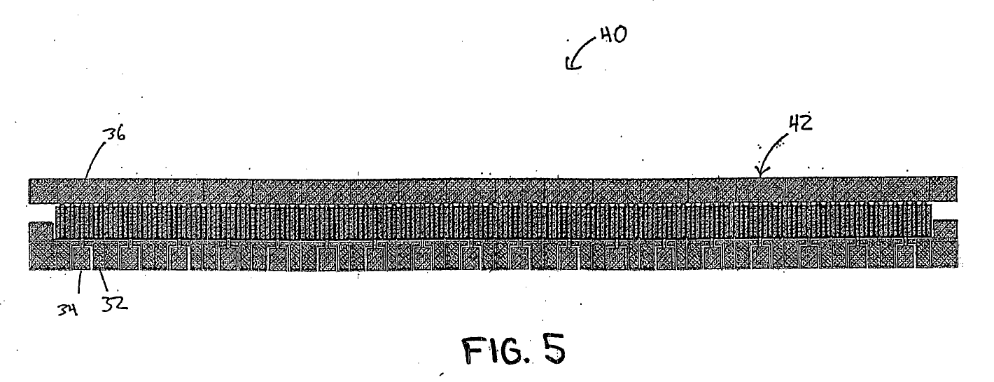

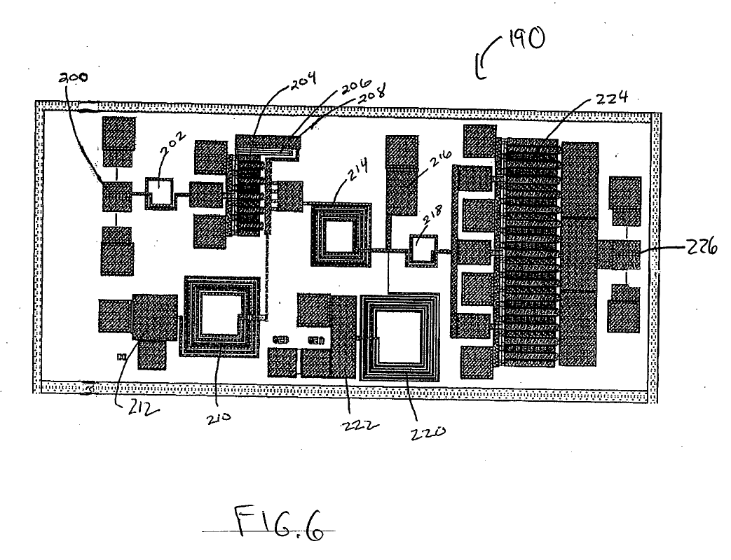

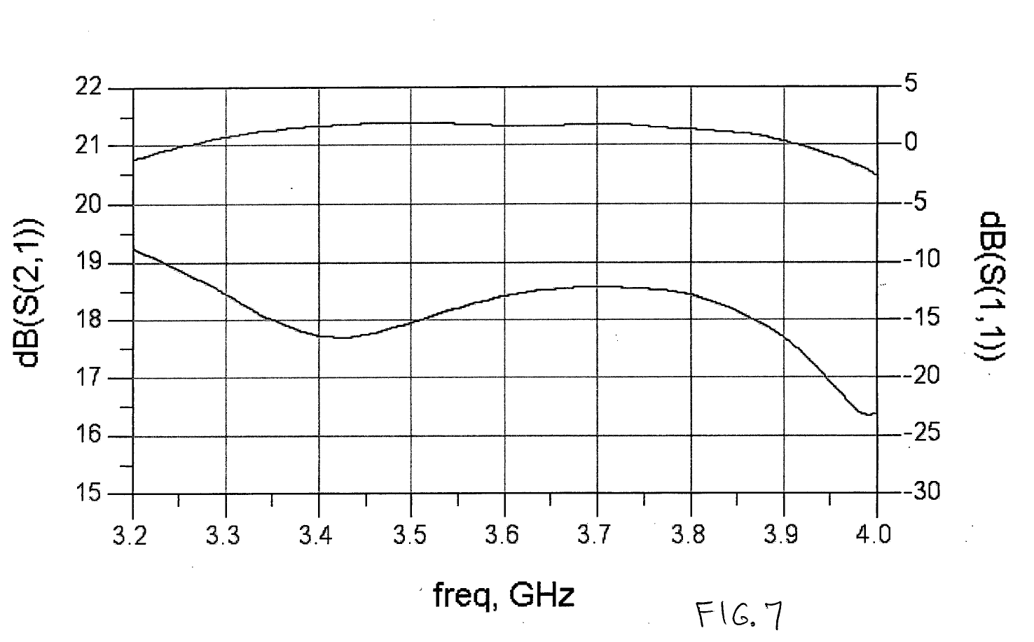

A GaN MMIC similar to the two-stage MMIC amplifier shown in FIG. 6 was designed to provide 1.0 Watts of linear power under OFDM modulation over a relatively wide band of frequency (3.3 to 3.9 GHz) with a supply voltage of 28 V. Small signal simulation results based on the operation of the amplifier were obtained using Advanced Design System software sold by Agilent. FIG. 7 shows a small signal gain of >20 dB and a return loss of less than −10 dB over the frequency range.

The results show that GaN-on-Si MMICs of the invention can exhibit exceptional bandwidth at frequencies greater than 3 GHz with high gains.

Having thus described several aspects of at least one embodiment of this invention, it is to be appreciated various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

What is claimed is:

1. A MMIC comprising:
a silicon substrate; and
at least one gallium nitride material-based device formed on the silicon substrate; and
at least one circuit element.

2. The MMIC of claim 1, wherein the circuit element is a semiconductor material-based device.

3. The MMIC of claim 1, wherein the circuit element is a gallium nitride material-based device.

4. The MMIC of claim 1, wherein the circuit element is formed on the silicon substrate.

5. The MMIC of claim 1, wherein the circuit element is formed on the gallium nitride material region.

6. The MMIC of claim 1, wherein the circuit element is a passive circuit element.

7. The MMIC of claim 1, wherein the circuit element is selected from one of an inductor, capacitor or resistor.

8. The MMIC of claim 1, wherein the circuit element is a diode.

9. The MMIC of claim 1, wherein the circuit element is electrically connected to the gallium nitride material-based device.

10. The MMIC of claim 1, wherein the MMIC is designed to receive an input signal and to transmit an output signal.

11. The MMIC of claim 10, wherein the MMIC amplifies the input signal to form the output signal.

12. The MMIC of claim 1, comprising a first gallium nitride material-based transistor and a second gallium nitride material-based transistor.

13. The MMIC of claims 1, further comprising at least one matching network adapted to transform an impedance of the MMIC.

14. The MMIC of claim 13, wherein the matching network includes at least one circuit element formed on the substrate.

15. The MMIC of claim 1, comprising an input matching network adapted to transform an input impedance of the MMIC and an output matching network adapted to transform an output impedance of the MMIC.

16. The MMIC of claim 1, comprising more than one circuit element.

17. The MMIC of claim 1, wherein the silicon substrate has a backside via formed therein.

18. The MMIC of claim 17, further comprising an electrode formed in the backside via

19. The MMIC of claim 1, wherein the MMIC is adapted to operate at a power density of at least 10 W/mm.

20. The MMIC of claim 1, wherein the MMIC is adapted to operate at a power density of at least 2 W/mm at an operating voltage of at least 10 Volts.

21. The MMIC of claim 1, wherein the MMIC is adapted to operate at a power density of greater than or equal to 4.0 W/mm at an operating voltage of at least 48 Volts.

22. The MMIC of claims 1, wherein the MMIC is adapted to transmit an output signal at a frequency of greater than 3 GHz at an operating voltage greater than or equal to 48 V.

23. The MMIC of claim 1, wherein the MMIC is adapted to transmit an output signal at a frequency of greater than 3 GHz at an operating voltage greater than or equal to 100 V.

24. The MMIC of claim 1, wherein the MMIC is adapted to transmit an output signal at a frequency of greater than 6 GHz.

25. The MMIC of claim 1, wherein the MMIC is adapted to transmit an output signal at a frequency of between about 8 GHz and about 12 GHz.

26. The MMIC of claim 1, wherein the MMIC is adapted to transmit an output signal with a power of greater than or equal to 10 W and at a frequency of between about 8 GHz and 12 GHz.

27. The MMIC of claim 1, wherein the MMIC is adapted to transmit at an output signal at a power of greater than about 100 Watts.

28. The MMIC of claim 1, wherein the MMIC is adapted to operate across a decade of bandwidth.

29. A MMIC comprising:
a silicon substrate; and
at least one semiconductor material-based device formed on the silicon substrate;
wherein the MMIC is adapted to operate at a power density of at least 2 W/mm.

30. A MMIC designed to transmit an output signal, the MMIC comprising:
a silicon substrate; and
at least one semiconductor material-based device formed on the silicon substrate;
wherein the MMIC is adapted to transmit an output signal at a frequency of greater than or equal to 3 GHz at an operating voltage greater than or equal to 28 V.
